(19) United States
(12) Patent Application Publication
(10) Pub. No.: US 2026/0060152 A1
(43) Pub. Date: Feb. 26, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chih-Hsien CHIU, Taichung City (TW); Chih-Chiang HE, Taichung City (TW); Chia-Chen CHIAO, Taichung City (TW)

(21) Appl. No.: 18/921,931

(22) Filed: Oct. 21, 2024

(30) Foreign Application Priority Data
Aug. 20, 2024 (TW) 113131312

(51) Int. Cl. H01L 23/498; H01L 21/48; H01L 23/00; H01L 23/31; H01L 25/00; H01L 25/065

(52) U.S. Cl. CPC H01L 23/49811; H01L 21/4857; H01L 23/3107; H01L 23/49822; H01L 24/19; H01L 24/20; H01L 25/0655; H01L 25/50; H01L 2224/19; H01L 2224/211

(57) ABSTRACT

Provided are an electronic package and a manufacturing method thereof, including a plurality of solder bumps formed on a carrier structure having an electronic component disposed thereon, a plurality of conductive pillars disposed on the solder bumps, an encapsulating layer covering the electronic component, the solder bumps and the conductive pillars, a wiring structure formed on the encapsulating layer. The solder bumps are connected to the carrier structure, and the conductive pillars are connected to the wiring structure. Hence, the carrier structure and the wiring structure are connected to each other by the solder bumps and the conductive pillars, thereby the problem of bridging short circuit between the solder bumps can be avoided.

### CROSS-REFERENCE TO RELATED APPLICATIONS

The present application is based upon and claims the right of priority to TW Patent Application No. 113131312, filed Aug. 20, 2024, the disclosure of which is hereby incorporated by reference herein in its entirety for all purposes.

### BACKGROUND

### 1. Technical Field

The present disclosure relates to a semiconductor packaging technology, and more particularly, to an electronic package and a manufacturing method thereof that meet the requirement of high density of contacts.

### 2. Description of Related Art

To ensure the continued miniaturization and multi-functionality of electronic products, semiconductor packaging needs to develop towards miniaturization to facilitate multi-pin interconnection and high functionality. For example, in advanced process packaging, commonly used packaging types include 2.5D packaging process, and Fan-Out wiring with embedded components processes, etc.

FIG. 1 is a schematic cross-sectional view illustrating a conventional semiconductor package 1. In the semiconductor package 1, a plurality of solder balls 13 and a semiconductor chip 11 having a plurality of electrode pads 110 are disposed on a substrate structure 10 having a circuit layer 101. An encapsulating layer 15 covers the semiconductor chip 11 and the solder balls 13. A wiring structure 16 is formed on the encapsulating layer 15 and electrically connected to the electrode pads 110 and the solder balls 13. A plurality of functional components 14 are disposed over the wiring structure 16 and are electrically connected thereto by a plurality of conductive bumps 17. A packaging layer 18 covers the functional components 14. In addition, the substrate structure 10 is disposed on a circuit board 1a through a plurality of solder bumps 12, and the solder balls 13 are electrically connected to the circuit layer 11.

However, in the semiconductor package 1, the substrate structure 10 and the wiring structure 16 are connected to each other by the solder balls 13, and the solder balls 13 are too large in the middle portion, which renders them susceptible to contact each other, resulting in a bridging short circuit. Therefore, the number of solder balls 13 is limited, leading to an insufficient number of contacts, and as a result, the specification of the semiconductor package 1 cannot meet the requirement of high density of contacts.

Therefore, how to overcome the various problems of the above-mentioned prior art has become an urgent issue to be solved.

### SUMMARY

In view of the various deficiencies of the prior art, the present disclosure provides an electronic package, the electronic package comprises: a carrier structure having a circuit layer and defined with a first side and a second side opposite to the first side; a plurality of solder bumps disposed on the first side of the carrier structure and electrically connected to the circuit layer; a plurality of conductive pillars disposed on the solder bumps; an electronic component disposed on the first side of the carrier structure and electrically connected to the circuit layer; an encapsulating layer formed on the first side of the carrier structure and encapsulating the solder bumps, the conductive pillars and the electronic component; and a wiring structure formed on the encapsulating layer and having a wiring layer electrically connected to the electronic component and the conductive pillars.

The present disclosure also provides a method of manufacturing an electronic package, the method comprises: providing a carrier structure having a circuit layer and defined with a first side and a second side opposite to the first side; forming a plurality of solder bumps on the first side of the carrier structure, and electrically connecting the solder bumps to the circuit layer; forming a plurality of conductive pillars on the solder bumps; disposing an electronic component on the first side of the carrier structure, and electrically connecting the electronic component to the circuit layer; forming an encapsulating layer on the first side of the carrier structure for encapsulating the solder bumps, the conductive pillars and the electronic component; and forming a wiring structure on the encapsulating layer, wherein the wiring structure is a wiring layer electrically connected to the electronic component and the conductive pillars.

In the electronic package and manufacturing method, the conductive pillars are metal pillars.

In the electronic package and manufacturing method, a plurality of conductive components are disposed on the wiring structure.

In the electronic package and manufacturing method, a functional component is disposed on the wiring structure.

In the electronic package and manufacturing method, a plurality of the electronic component are embedded in the encapsulating layer.

In the electronic package and manufacturing method, an electronic device electrically connected to the circuit layer is disposed on the second side of the carrier structure. For instance, the electronic device is a semiconductor chip and a packaging module.

The electronic package and manufacturing method further comprises a packaging layer covering the carrier structure and the encapsulating layer. For instance, the wiring structure is further formed on the packaging layer.

In the electronic package and manufacturing method, a width of the carrier structure is smaller than a width of the wiring structure.

As can be seen from the above, in the electronic package and manufacturing method of the present disclosure, the solder bumps are connected to the carrier structure, and the conductive pillars are connected to the wiring structure, whereby the carrier structure and the wiring structure are connected to each other by the solder bumps and the conductive pillars. Compared to prior art, a volume of the conductive pillar of the present disclosure is much smaller than that of the conventional solder ball at middle portion, and thus would not contact with each other, thereby the problem of bridging short circuit can be avoided. As such, a number of conductive pillars can be greatly increased without the problem of few contacts, and is beneficial for the specifications of the electronic package of the present disclosure on meeting the requirement for high density contacts.

### BRIEF DESCRIPTION OF THE DRAWINGS

FIG. 1 is a schematic cross-sectional view illustrating a conventional semiconductor package.

FIG. 2A to FIG. 2E are schematic cross-sectional views illustrating a manufacturing method of an electronic package according to the first embodiment of the present disclosure.

FIG. 3A to FIG. 3D are schematic cross-sectional views illustrating a manufacturing method of an electronic package according to the second embodiment of the present disclosure.

FIG. 3E is a schematic bottom view of FIG. 3D.

FIG. 4A to FIG. 4C are schematic cross-sectional views illustrating an electronic package according to different embodiment of the present disclosure.

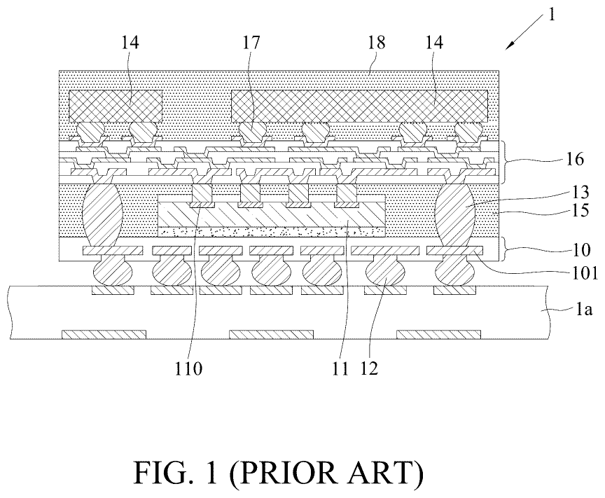

### DETAILED DESCRIPTION

Embodiments of the present disclosure are described below with specific examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “first,” “second,” “a,” “one” and the like are merely for clear explanation rather than limiting the practicable scope of the present disclosure, and thus, alterations or adjustments of the relative relationships thereof without essentially altering the technical contents should still be considered in the practicable scope of the present disclosure.

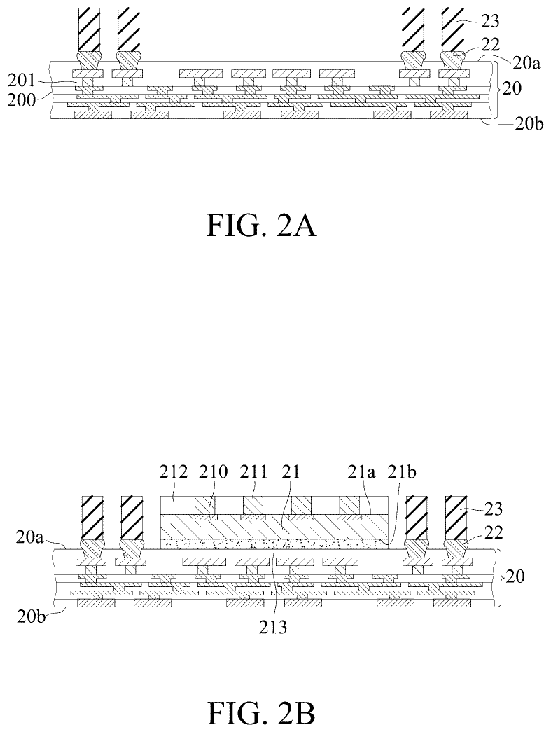

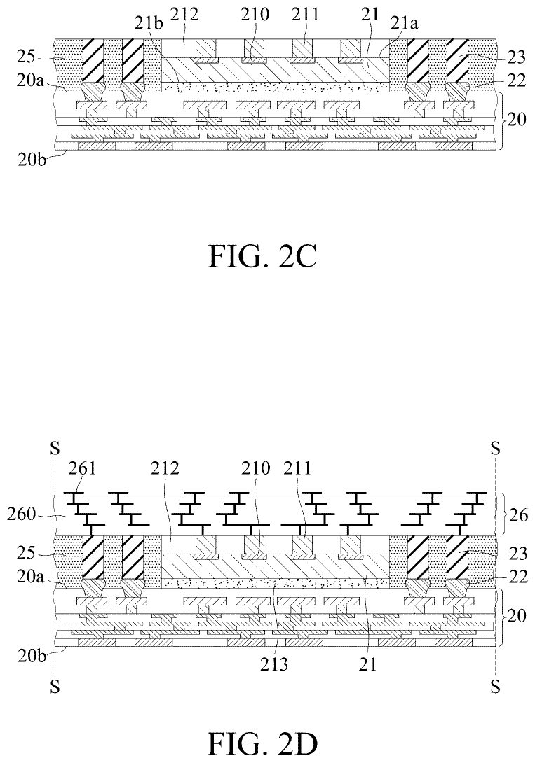

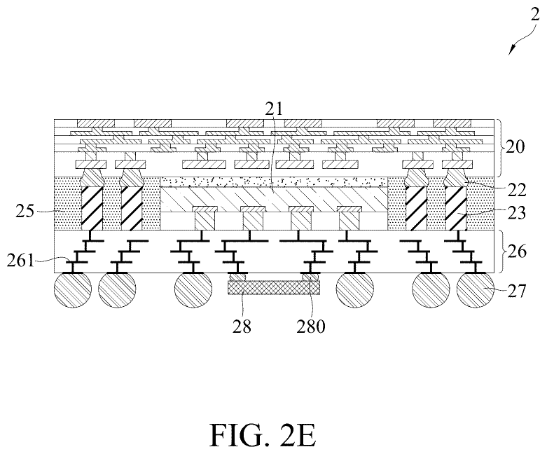

FIG. 2A to FIG. 2E are schematic cross-sectional views illustrating a manufacturing method of an electronic package 2 according to the first embodiment of the present disclosure.

As shown in FIG. 2A, a carrier structure 20 having a first side 20a and a second side 20b opposite to the first side 20a is provided. A plurality of solder bumps 22 are formed on the first side 20a of the carrier structure 20, and a plurality of conductive pillars 23 are formed on the solder bumps 22.

In one embodiment, the carrier structure 20 is, for example, a packaging substrate having a core layer and a circuit structure, a packaging substrate having a coreless circuit structure, a through silicon interposer (TSI) having through silicon vias (TSVs), or other types or boards. The carrier structure 20 includes at least one first dielectric layer 200 and at least one circuit layer 201 bonded to the first dielectric layer 200, such as at least one fan-out redistribution layer (RDL).

Further, the circuit layer 201 is made of copper, and the conductive pillars 23 are metal pillars such as copper pillars. For instance, the conductive pillars 23 are disposed upright on the solder bumps 22, and then the solder bumps 22 are subjected to a reflow process.

In addition, the first dielectric layer 200 is made of, for example, polybenzoxazole (PBO), polyimide (PI), prepreg (PP), or other dielectric materials.

It should be understood that the carrier structure 20 may also be any other substrates carrying chips, such as a lead frame, a wafer, a board having metal routings, and the like, and is not limited to as such.

As shown in FIG. 2B, an electronic component 21 is disposed on the first side 20a of the carrier structure 20. The electronic component 21 is an active component, a passive component, or a combination thereof. The active component is, for example, a semiconductor chip, and the passive component is, for example, a resistor, a capacitor, and an inductor.

In one embodiment, the electronic component 21 is a semiconductor chip and has an active surface 21a and an inactive surface 21b opposite to the active surface 21a. The electronic component 21 is disposed on the first side 20a of the carrier structure 20 via its inactive surface 21b through an adhesive layer 213 (e.g., a thermal conductive adhesive). The active surface 21a has a plurality of electrode pads 210 for connecting to a plurality of conductors 211 being such as column shape, stud shape, or other bump shape. An insulating protective film 212 is formed on the active surface 21a for covering the conductors 211, and thus the conductors 211 are exposed from the insulating protective film 212.

It should be understood that in the process sequence, on the carrier structure 20, the electronic component 21 can be provided first, and the solder bumps 22 and the conductive pillars 23 can be formed subsequently.

As shown in FIG. 2C, an encapsulating layer 25 is formed on the first side 20a of the carrier structure 20. The encapsulating layer 25 covers the electronic components 21, the solder bumps 22 and the conductive pillars 23.

In one embodiment, the encapsulating layer 25 is made of an insulating material, such as polyimide (PI), a dry film, or an encapsulant or a molding compound such as epoxy (epoxy resin), but is not limited to as such. For instance, the encapsulating layer 25 is formed on the first side 20a of the carrier structure 20 by lamination or molding, or other manners.

Moreover, a leveling process is performed as needed. An upper surface of the encapsulating layer 25 is made flush with end surfaces of the conductive pillars 23, a surface of the insulating protective film 212, and end surfaces of the conductors 211, such that the end surfaces of the conductive pillars 23, the surface of the insulating protective film 212, and the end surfaces of the conductors 211 are exposed from the encapsulating layer 25. For example, a leveling process can be performed via grinding, whereby parts of materials from the conductive pillars 23, parts of materials of the insulating protective film 212, parts of materials from the conductors 211, and parts of material from the encapsulating layer 25 are removed.

As shown in FIG. 2D, a wiring structure 26 is formed on the encapsulating layer 25 and electrically connected to the conductive pillars 23 and the conductors 211.

In one embodiment, the wiring structure 26 includes at least one second dielectric layer 260 and at least one wiring layer 261 formed on the second dielectric layer 260, such as a redistribution layer (RDL), the wiring layer 261 of the wiring structure 26 is electrically connected to the conductive pillars 23 and the conductors 211, and thus the wiring structure 26 is electrically connected to the electrode pads 210 through the conductors.

Furthermore, the wiring layer 261 is made of copper, and the second dielectric layer 260 is made of, such as polybenzoxazole (PBO), polyimide (PI), or prepreg (PP), or other dielectric material.

As shown in FIG. 2E, a singulation process is performed alone a cutting path S shown in FIG. 2D, such that a plurality of electronic packages 2 are obtained.

In one embodiment, in a sequence process, a plurality of conductive components 27 such as solder balls or other metal bumps (e.g., copper pillars) are formed on the wiring layer 261 of the wiring structure 26, allowing the electronic package 2 to be bonded to an electronic device (not shown), such as a circuit board, through the conductive components 27.

In one embodiment, in a sequence process, a plurality of functional components 28 may be disposed on the wiring layer 261 of the wiring structure 26. The functional components 28 can be, for example, active components, passive components, package structures, or combinations thereof. The active component is, for example, a semiconductor chip, and the passive component is, for example, a resistor, a capacitor, or an inductor.

Further, the functional components 28 are disposed on the wiring layer 261 of the wiring structure 26 in a flip-chip manner via a plurality of conductive bumps 280, such as solder bumps, copper bumps, or others. It should be appreciated that there are many ways for electrical connection of the functional components 28 between the wiring structure 26, such as by wire packaging, including but not limited to the foregoing.

Therefore, in the manufacturing method of the above embodiment, the solder bumps 22 are connected to the carrier structure 20, and the conductive pillars 23 are connected to the wiring structure 26, whereby the carrier structure 20 and the wiring structure 26 are connected to each other by the solder bumps 22 and the conductive pillars 23. Compared to prior art, a volume of the conductive pillar of the present disclosure is much smaller than that of the conventional solder ball at middle portion, and thus would not contact with each other, thereby the problem of bridging short circuit can be avoided. As such, a number of the conductive pillars can be greatly increased without the problem of few contacts, and is beneficial for the specifications of the electronic package 2 of the present disclosure on meeting the requirement for high density contacts.

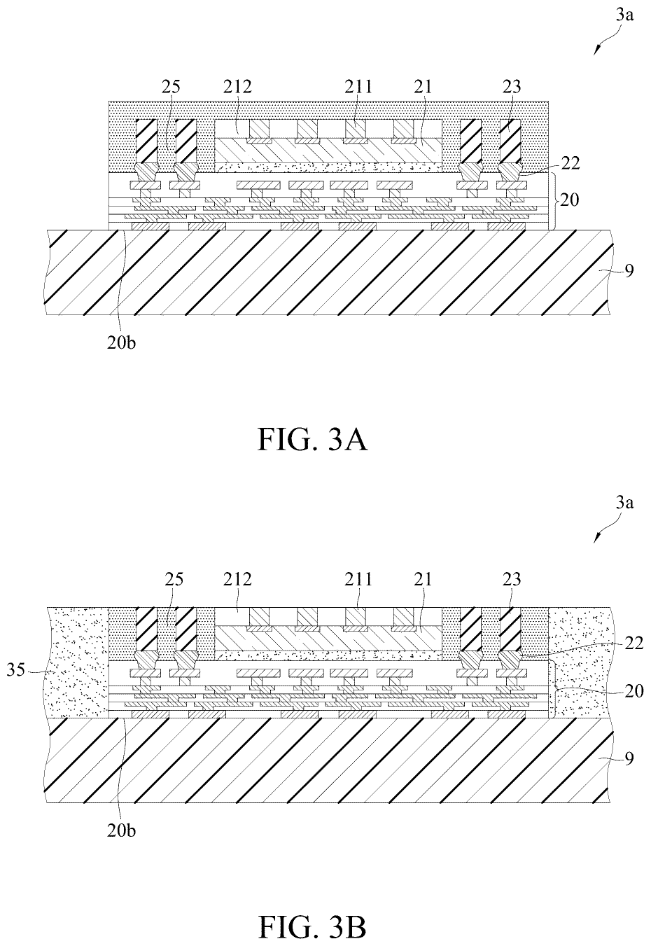

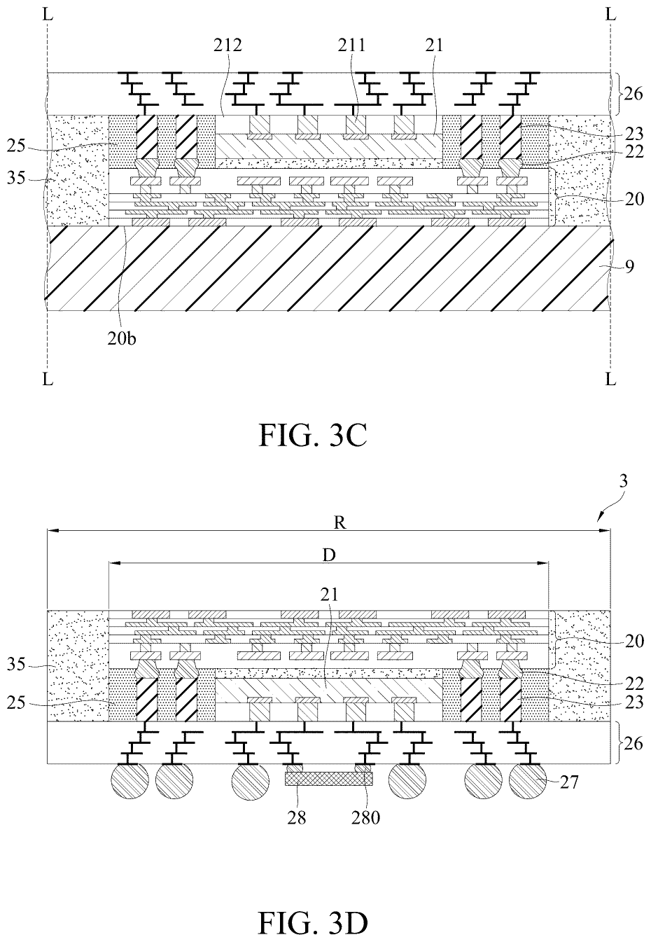

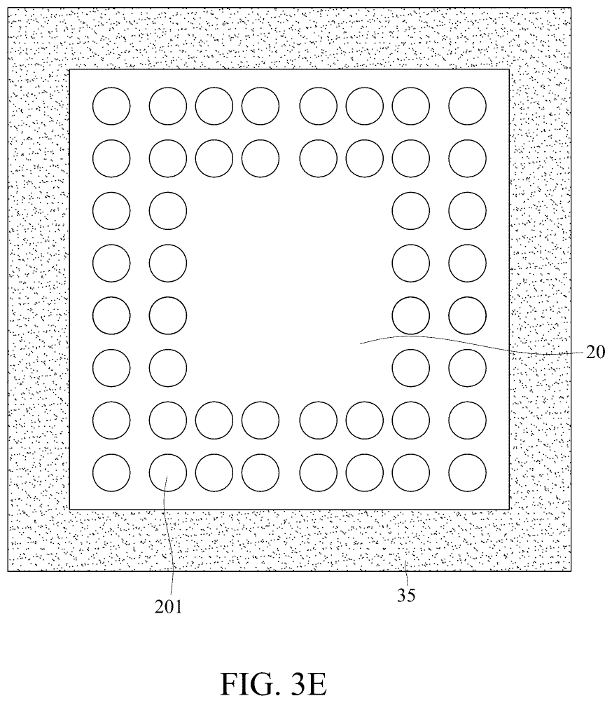

FIG. 3A to FIG. 3D are schematic cross-sectional views illustrating a manufacturing method of an electronic package according to the second embodiment of the present disclosure.

As shown in FIG. 3A, a singulation process, which is continued with the process shown in FIG. 2C, is performed to obtain a plurality of electronic modules 3a. Then, the electronic modules 3a are disposed on a carrier 9.

In one embodiment, the carrier 9 is a board made of, for example, but not limited to, a semiconductor material, a dielectric material, a ceramic material, a glass material, or a metal material, and the dimensions of the carrier 9 can be selected from a wafer form substrate or a panel form substrate as needed. A bonding layer, such as a release film or an adhesive, can be formed on the board by coating or laminating, such that the electronic modules 3a are bonded to the bonding layer.

As shown in FIG. 3B, a packaging layer 35 is formed on the carrier 9 and covers the electronic modules 3a.

In one embodiment, the packaging layer 35 covers the encapsulating layer 25 and the carrier structure 20.

Furthermore, the packaging layer 35 is made of an insulating material, such as polyimide (PI), a dry film, or an encapsulant or a molding compound such as epoxy (epoxy resin). The packaging layer 35 is formed on the carrier 9 by lamination or molding, or other manners. It should be understood that materials for the packaging layer 35 and the encapsulating layer 25 may be the same or different.

Moreover, a leveling process is performed as needed. An upper surface of the packaging layer 35 is made flush with an upper surface of the encapsulating layer 25, end surfaces of the conductive pillars 23, a surface of the insulating protective film 212, and end surfaces of the conductors 211, such that the end surfaces of the conductive pillars 23, the surface of the insulating protective film 212, and the end surfaces of the conductors 211 are exposed from the packing layer 35 and the encapsulating layer 25. For example, a leveling process can be performed via grinding, whereby part of materials from the packing layer 35, parts of materials from the conductive pillars 23, parts of materials of the insulating protective film 212, parts of materials from the conductors 211, and parts of material from the encapsulating layer 25 are removed.

As shown in FIG. 3C, a wiring structure 26 is formed on the encapsulating layer 25 and the packing layer 35 and is electrically connected to the conductive pillars 23 and the conductors 211.

As shown in FIG. 3D, the carrier 9 is removed. A singulation process is performed along a cutting path L shown in FIG. 3C to obtain a plurality of electronic package 3.

In one embodiment, a width D of the carrier structure 20 is smaller than a width R of the wiring structure 26. As shown in FIG. 3E, the packing layer 35 covers sides of the carrier structure 20 to prevent the carrier structure 20 from being damaged.

In one embodiment, in a sequence process, a plurality of conductive components 27 and a functional component 28 may be disposed on the wiring layer 261 of the wiring structure 26.

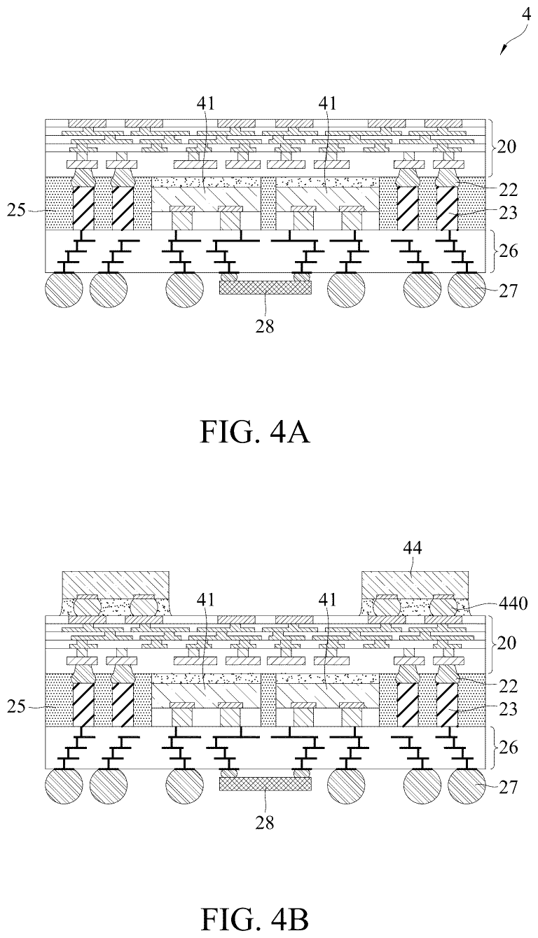

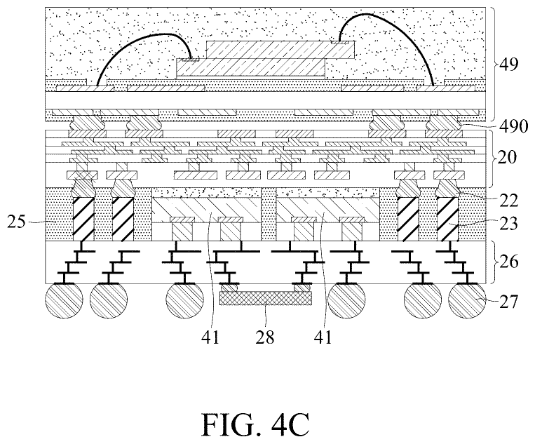

In addition, based on the first and second embodiments, in another embodiment, as shown in FIG. 4A, a plurality of electronic components 41 may also be embedded in an electronic package 4. As shown in FIG. 4B and FIG. 4C, other electronic device 44, 49 may be disposed on the second side 20b of the carrier structure 20, such as semiconductor chips shown in FIG. 4B or a packaging module shown in FIG. 4C.

The semiconductor chip is electrically connected to the circuit layer 201 in a flip-chip manner via a plurality of conductive bumps 440, such as solder bumps, copper bumps, or others. It should be appreciated that there are many ways in which the semiconductor chip can be electrically connected to the circuit layer 201, such as by wire packaging, including but not limited to the foregoing.

The packaging module is, for example, dynamic random access memory (DRAM) and stacked on the carrier structure 20 via a plurality of conductive bumps 490, such as solder bumps, copper bumps, or others.

Additionally, the specifications of the electronic components 21, 41, the functional component 28, and the electronic device 44, 49 can be adjusted as needed.

Therefore, in the manufacturing method of the above embodiment, the solder bumps 22 are connected to the carrier structure 20, and the conductive pillars 23 are connected to the wiring structure 26, whereby the carrier structure 20 and the wiring structure 26 are connected to each other by the solder bumps 22 and the conductive pillars 23. Compared to prior art, a volume of the conductive pillar of the present disclosure is much smaller than that of the conventional solder ball at middle portion, and thus would not contact with each other, thereby the problem of bridging short circuit can be avoided. As such, a number of the conductive pillars can be greatly increased without the problem of few contacts, and is beneficial for the specifications of the electronic package 3 of the present disclosure to meet the requirement for high density contacts.

An electronic package 2, 3, 4 is further provided. The electronic package 2, 3, 4 includes a carrier structure 20 having a circuit layer 201, a plurality of solder bumps 22, a plurality of conducive pillars, at least one electronic component 21, 41, an encapsulating layer 25, and wiring structure 26.

The carrier structure 20 is defined with a first side 20a and a second side 20b opposite to the first side 20a.

The solder bumps 22 are disposed on the first side 20a of the carrier structure 20 and electrically connected to the circuit layer 201.

The conductive pillars 23 are disposed on the solder bumps 22.

The electronic component 21, 41 is disposed on the first side 20a of the carrier structure 20 and electrically connected to the circuit layer 210.

The encapsulating is formed on the first side 20a of the carrier structure 20 and covers the solder bumps 22, the conductive posts 23, and the conductive component 21.

The wiring structure 26 is disposed on the encapsulating layer 25 and includes at least one wiring layer 261 electrically connected to the conductive component 21, 41, and the conductive pillars 23.

In one embodiment, the conductive pillars 23 are metal pillars.

In one embodiment, a plurality of conductive components 27 are disposed on the wiring structure 26.

In one embodiment, a functional component 28 is disposed on the wiring structure 26.

In one embodiment, a plurality of the conducive components 41 are embedded in the encapsulating layer 25.

In one embodiment, at least one electronic device 44, 29 electrically connected to the circuit layer 201 is disposed on the second side 20b of the carrier structure 20. For instance, the electronic device 44, 49 is a semiconductor chip or a packaging module.

In one embodiment, the electronic package 3 further comprises a packaging layer 35 covering the carrier structure 20 and the encapsulating layer 25. For instance, the wiring structure 26 is further formed on the packaging layer 35.

In one embodiment, a width D of the carrier structure 20 is smaller than a width R of the wiring structure 26.

In conclusion, in the electronic package and manufacturing method of the present disclosure, the solder bumps are connected to the carrier structure, and the conductive pillars are connected to the wiring structure, whereby the carrier structure and the wiring structure are connected to each other by the solder bumps and the conductive pillars. Accordingly, the volume of the conductive pillar at the middle portion is much smaller than the conventional solder ball, and thus does not contact each other, thereby avoiding the problem of bridging short circuit. As such, a number of the conductive pillars can be greatly increased without the problem of few contacts, and is beneficial for the specifications of the electronic package of the present disclosure to meet the requirement for high density contacts.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a carrier structure having a circuit layer and defined with a first side and a second side opposite to the first side;
a plurality of solder bumps disposed on the first side of the carrier structure and electrically connected to the circuit layer;
a plurality of conductive pillars disposed on the solder bumps;
an electronic component disposed on the first side of the carrier structure and electrically connected to the circuit layer;
an encapsulating layer formed on the first side of the carrier structure and encapsulating the solder bumps, the conductive pillars and the electronic component; and
a wiring structure formed on the encapsulating layer and having a wiring layer electrically connected to the electronic component and the conductive pillars.

2. The electronic package of claim 1, wherein the conductive pillars are metal pillars.

3. The electronic package of claim 1, wherein a plurality of conductive components are disposed on the wiring structure.

4. The electronic package of claim 1, wherein a functional component is disposed on the wiring structure.

5. The electronic package of claim 1, wherein a plurality of the electronic component are embedded in the encapsulating layer.

6. The electronic package of claim 1, wherein an electronic device electrically connected to the circuit layer is disposed on the second side of the carrier structure.

7. The electronic package of claim 6, wherein the electronic device is a semiconductor chip and a packaging module.

8. The electronic package of claim 1, further comprising a packaging layer covering the carrier structure and the encapsulating layer.

9. The electronic package of claim 8, wherein the wiring structure is further formed on the packaging layer.

10. The electronic package of claim 1, wherein a width of the carrier structure is smaller than a width of the wiring structure.

11. A method of manufacturing an electronic package, the method comprising:
providing a carrier structure having a circuit layer and defined with a first side and a second side opposite to the first side;
forming a plurality of solder bumps on the first side of the carrier structure, and electrically connecting the solder bumps to the circuit layer;
forming a plurality of conductive pillars on the solder bumps;
disposing an electronic component on the first side of the carrier structure, and electrically connecting the electronic component to the circuit layer;
forming an encapsulating layer on the first side of the carrier structure for encapsulating the solder bumps, the conductive pillars and the electronic component; and
forming a wiring structure on the encapsulating layer, wherein the wiring structure is a wiring layer electrically connected to the electronic component and the conductive pillars.

12. The method of claim 11, wherein the conductive pillars are metal pillars.

13. The method of claim 11, wherein a plurality of conductive components are disposed on the wiring structure.

14. The method of claim 11, wherein a functional component is disposed on the wiring structure.

15. The method of claim 11, wherein a plurality of the electronic component are embedded in the encapsulating layer.

16. The method of claim 11, wherein an electronic device electrically connected to the circuit layer is disposed on the second side of the carrier structure.

17. The method of claim 16, wherein the electronic device is a semiconductor chip and a packaging module.

18. The method of claim 11, further comprising forming a packaging layer to cover the carrier structure and the encapsulating layer.

19. The method of claim 18, wherein the wiring structure is further formed on the packaging layer.

20. The method of claim 11, wherein a width of the carrier structure is smaller than a width of the wiring structure.
